(19) United States
(12) Patent Application Publication
(10) Pub. No.: US 2022/0397354 A1
(43) Pub. Date: Dec. 15, 2022

(54) COLD CONDUIT INSULATION DEVICE

(71) Applicant: Watlow Electric Manufacturing Company, St. Louis, MO (US)

(72) Inventor: John LILLELAND, Morgan Hill, CA (US)

(73) Assignee: Watlow Electric Manufacturing Company, St. Louis, MO (US)

(21) Appl. No.: 17/836,307

(22) Filed: Jun. 9, 2022

Related U.S. Application Data
(60) Provisional application No. 63/208,818, filed on Jun. 9, 2021.

(51) Int. Cl. F28F 21/08

(52) U.S. Cl. CPC F28F 21/089; H01L 21/68785

(57) ABSTRACT

A thermal insulation structure includes an insulation layer having a first surface proximate a cooling device and a second surface opposing the first surface. A heater is disposed proximate the second surface, and a protective layer is disposed proximate the heater layer such that the heater layer is disposed between the insulation layer and the protective layer. The heater layer is configured to reduce frost or ice buildup on an exterior surface of the insulation layer.

### CROSS-REFERENCE TO RELATED APPLICATION

This application claims priority to and the benefit of U.S. Provisional Patent Application No. 63/208,818, filed Jun. 9, 2021. The disclosure of the above application is incorporated herein by reference in its entirety.

### FIELD

The present disclosure relates to thermal insulation devices, and more particularly to thermal insulation devices for cold conduits.

### BACKGROUND

The statements in this section merely provide background information related to the present disclosure and may not constitute prior art.

Semiconductor manufacturing may require a wafer to be cooled in certain processing steps. Typically, a cooling device is integrated into a wafer support pedestal to provide cooling to the wafer. The cooling device is connected to a coolant conduit, which in turn is connected to an external cooling source, such as a heat exchanger. A thermal insulation structure is generally disposed around the coolant conduit to maintain the temperature of the coolant at a predetermined low temperature. When a coolant of a very low temperature, such as −40° C., or even −80° C., is desired, the thickness of the thermal insulation structure is increased to increase thermal insulation. However, space may be limited in the semiconductor manufacturing equipment, and thus increasing the thickness of the thermal insulation structure may not be feasible.

Moreover, due to sub-zero temperature of the coolant conduit, frost or ice may build up on the outer surface of the coolant conduit, causing moisture to permeate into the thermal insulation structure. The moisture may reduce the thermal resistance (i.e., thermal insulation) of the thermal insulation structure and may subject the insulation structure to a risk of thermal short-circuiting.

The present disclosure addresses these and other issues associated with thermal insulation for a coolant conduit.

### SUMMARY

This section provides a general summary of the disclosure and is not a comprehensive disclosure of its full scope or all of its features.

In one form, a thermal insulation device includes an insulation layer having a first surface proximate a cooling device and a second surface opposing the first surface, a heater layer disposed proximate the second surface, and a protective layer disposed proximate the heater layer such that the heater layer is disposed between the insulation layer and the protective layer.

In variations of this thermal insulation device, which may be implemented individually or in any combination: the insulation layer defines a tubular body, the first surface being an inner surface and the second surface being an outer surface of the tubular body; the heater layer surrounds the insulation layer, and the protective layer surrounds the heater layer; the heater layer is configured to reduce frost or ice buildup on an exterior surface of the insulation layer; a vapor barrier layer is disposed between the protective layer and the insulation layer; the insulation layer includes a material selected from a group consisting of polyisocyanurate, polyurethane, expanded polystyrene, silicone foam, polyethylene foam, aerogels, and combinations thereof; the insulation layer includes a monolith body; the insulation layer comprises a composite structure; the insulation layer includes an aerogel material as a primary constituent; a dielectric layer and a vapor barrier layer are disposed between the protective layer and the insulation layer; the vapor barrier layer is an aluminum material or a metal thin film on a polymer film; the dielectric layer is a polyimide material or a reinforced silicone rubber material; the heater layer comprises a polyimide heater; and the heater layer comprises a layered heater. The thermal insulation device may further include a power generating device for supplying an induced voltage to the heater layer. The induced voltage is induced by a temperature difference in the power generating device. The power generating device includes a first conductive portion and a second conductive portion that are joined and that are made of different materials. The first and second conductive portions are disposed proximate external components having different temperatures such that the temperature difference is generated between the first and second conductive portions.

In another form, a thermal insulation device includes a tubular insulation layer defining a central opening for receiving a coolant conduit therein, a heater layer disposed around the tubular insulation layer, a protective layer disposed around the heater layer, a dielectric layer disposed between the heater layer and the protective layer, and a vapor barrier layer disposed between the heater layer and the protective layer. In an alternate form, the heater layer is disposed around the protective layer.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 is a schematic cross-sectional view of a thermal insulation device adapted to be mounted around a coolant conduit and constructed in accordance with the teachings of the present disclosure;

FIG. 2 is an enlarged view of portion A of FIG. 1;

FIG. 3 is a schematic cross-sectional view of a power generating device constructed in accordance with the teachings of the present disclosure; and

FIG. 4 is a schematic cross-sectional view of a variant of a power generating device constructed in accordance with the teachings of the present disclosure.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

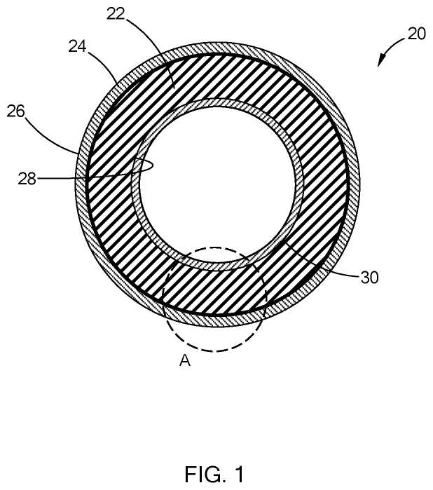

Referring to FIG. 1, a thermal insulation device 20 constructed in accordance with the teachings of the present disclosure includes an insulation layer 22, a heater layer 24 disposed around the insulation layer 22, and a protective layer 26 disposed around the heater layer 24. In one form, the insulation layer 22 may has a tubular configuration defining a central opening 28 for receiving a cold object, such as a coolant conduit 30, therein. In another form, the insulation layer 22 may have a blanket or a sheet configuration which can be wrapped around the cold object, and the heater layer 24 and the protective layer 26 are disposed on an outer surface of the insulation layer 22 opposing the cold object. The coolant conduit 30 may extend from an external cold source (not shown), such as a heat exchanger, to a cooling device. As an example, the cooling device may be integrated into an electrostatic chuck or a wafer support pedestal in a semiconductor manufacturing apparatus. A coolant flows in the coolant conduit 30 and provides a desired cooling to a cooling target, e.g., the wafer.

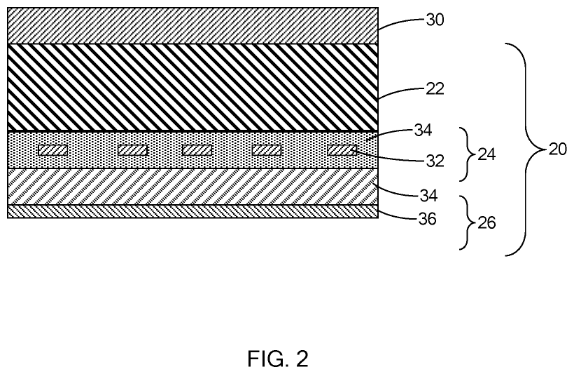

Referring to FIG. 2, the insulation layer 22 may be a single monolith body in one form. The insulation layer 22 may include a closed cell porous material, such as polyisocyanurate (PIMA), polyurethane, expanded polystyrene (EPS), silicone foam, polyethylene (PE) foam, or an open cell material such as aerogel. If an open cell material is used, the insulation layer 22 should be chemically treated to become hydrophobic to avoid moisture permeation. Alternatively, the closed cell porous material and the open cell material may be integrated into one composite structure. For example, a composite structure including aerogel as the primary insulating constituent and polyurethane as a supplemental material may be used. In another variation, heat (such as the heater layer 24 as described herein) may be used as a substitute for the hydrophobic chemical treatment. The insulation layer 22 may have various constructions with a thickness from about 3 to 10 mm. Aerogel has a high thermal resistance, about three times the thermal resistance of a conventional foam material. When aerogel is used as the primary insulating constituent in the insulation layer 22, the thickness of the insulation layer 22 can be significantly reduced.

The heater layer 24 is disposed on an outer surface of the insulation layer 22 to reduce frost or ice buildup on the insulation layer 22, particularly on an inner surface of the insulation layer 22 adjoining the coolant conduit 30. The heater layer 24 in one form is a low wattage heater layer having a wattage of less than about 1 watt/int with a voltage between approximately 5 to 48V. The heater layer 24 may have any type of construction, for example, a layered heater or an etched foil polyimide heater. A layered heater generally includes layers of different materials, namely, a dielectric material and a resistive material, by accumulating, depositing, printing, or spraying the different materials on a substrate. In one form, the heater layer 24 comprises a carbon fiber or metal mesh. In this variation, the heater layer 24 serves a dual function of providing heat and also providing reinforcement. Further, the heater layer 24 may also be integrated within the protective layer 26, or a flexible outer jacket. The heater layer 24 generally includes a resistive heating element 32 and a dielectric layer 34 In one form, the resistive heating element 32 is an Inconel® nickel alloy, or may alternately be a copper alloy. The dielectric layer 34 may be a polyimide film or a reinforced silicone rubber sheet. When a voltage is applied to the resistive heating element 32, the resistive heating element 32 generates heat to remove the frost or ice buildup on the outer surface of the protective layer 26. Accurate temperature control or temperature sensing as typically implemented in other applications is not a design driver in the thermal insulation device 20, as the main purpose of the heater layer 24 is to reduce frost or ice buildup.

By inhibiting frost or ice buildup on the thermal insulation device 20, the insulation layer 22 is better protected against moisture damage. Accordingly, there is a reduced emphasis on sealing gaps that may be present in the thermal insulation device 20, as opposed to a typical insulation structure where sealing of gaps is prevalent to protect the thermal insulation material against moisture damage. As a result, manufacturing costs can be reduced.

The insulation layer 22 is protected against moisture permeation from the inside by using the heater layer 24, and from the outside by using the protective layer 26. The thermal insulation device further includes a dielectric layer 34 proximate the heater layer 24 for electrically insulating the heater layer 24, and a vapor barrier layer 36. The vapor barrier layer 36 is the outermost layer of the thermal insulation device 20 to reduce the chance of atmospheric moisture diffusing into the bulk insulation of the thermal insulation device 20 and lowering the thermal resistance, creating a thermal short-circuit. In an alternate design, the vapor barrier layer 36 is inside the heater layer 24 (not shown). In this form, the vapor barrier layer 36 is made of a metal material and functions as a diffuser to improve thermal uniformity around the protective layer 26. The dielectric layer 34 may include, by way of example, silicone rubber, silicone rubber fiberglass, rubber, polyethylene, polyurethane, polyester, PTFE (polytetrafluoroethylene), FEP (fluorinated ethylene propylene), PFA (perfluoroalkoxy alkanes) and polyimide, among others. The vapor barrier layer 36 in one form is an aluminum layer.

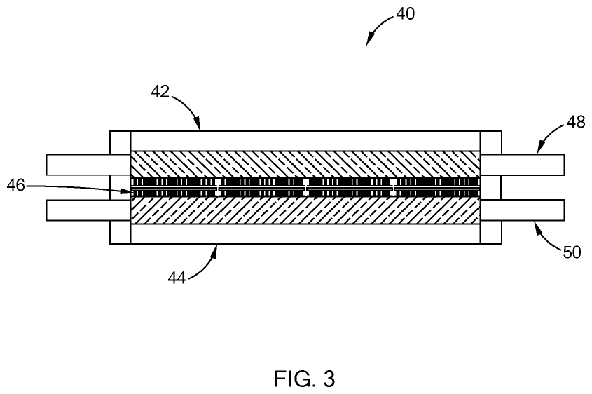

Referring to FIG. 3, a power generating device 40 constructed in accordance with teachings of the present disclosure may be used to provide power to the thermal insulation device 20. The power generating device 40 includes a first conductive portion 42 made of a first material and a second conductive portion 44 made of a second material dissimilar to the first material 42. The first and second conductive portions 42 and 44 are electrically conductive. In other words, the first and second materials have different Peltier coefficients, or Seebeck coefficients taking into account absolute temperature. The first conductive portion 42 is joined to the second conductive portion 44 to form a junction 46. The power generating device 40 may be disposed proximate to a first manifold 48 carrying a cold fluid and a second manifold 50 carrying a hot fluid such that the first conductive portion 42 is cooled by the first manifold 48 and the second conductive portion 44 is heated by the first manifold 48, thereby creating a temperature difference between the first conductive portion 42 and the second conductive portion 44. The temperature difference causes a voltage to be induced across the junction 46 due to the Peltier effect, making the power generating device 40 a thermoelectric generator.

The first manifold 48 and the second manifold 50 may be disposed outside the first and second conductive portions 42, 44 or may extend through the first and second conductive portions 42, 44. In one form, the first manifold 48 and the second manifold 50 may be a part of or an extension from the manifolds that are already present in the semiconductor manufacturing apparatus for other cooling or heating purposes. While the voltage induced by the temperature difference is relatively low, the voltage is sufficient to allow the heater layer 24 of the thermal insulation device 20 of FIGS. 1 and 2 to generate sufficient heat to remove frost or ice buildup.

Alternatively, instead of using the first and manifolds 48, 50, the first conductive portion 42 and the second conductive portion 44 may be disposed proximate any cold component and hot component that are already present in the semiconductor manufacturing apparatus. Therefore, an existing cold component can be used to cool the first conductive portion 42 while performing its main function and an existing hot component can be used to heat the second conductive portion 44 while performing its main function.

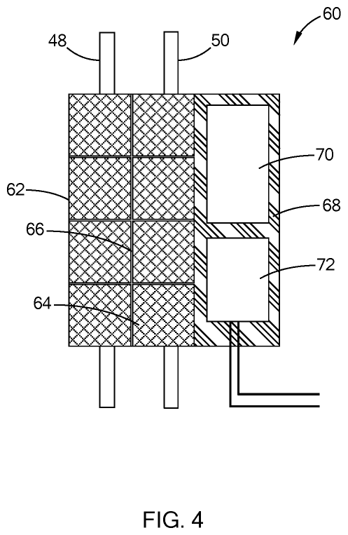

Referring to FIG. 4, a variant of a power generating device 60 constructed in accordance with the teachings of the present disclosure includes a first conductive portion 62 including a first material, and a second conductive portion 64 including a second material dissimilar to the first material. The first conductive portion 62 is joined to the second conductive portion 64 to form a junction 66. The first conductive portion 62 is disposed on the first manifold 48 carrying a cold fluid. The second conductive portion 64 is disposed on the second manifold 50 carrying a hot fluid. The power generating device 60 further includes a third component 68 on which a power storage device 70 and a control circuit 72 are disposed.

By using the first manifold 48 and the second manifold 50 to create a temperature difference between the first conductive portion 60 and the second conductive portion 62, a voltage is induced across the junction 66. The induced voltage may be stored in the power storage device 70, such as a capacitor. The control circuit 76 may be connected to the thermal insulation device 20 of FIGS. 1 and 2 to control power supply from the power storage device 70 to the thermal insulation device 20.

It is understood that the power generating devices 40, 60 may be used to supply power to any electric device, such as by way of example a microcontroller or data collection electronics (not shown), other than the thermal insulation device 20 of FIGS. 1 and 2 without departing from the scope of the present disclosure.

Unless otherwise expressly indicated herein, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, material, manufacturing, and assembly tolerances, and testing capability.

As used herein, the phrase at least one of A, B, and C should be construed to mean a logical (A OR B OR C), using a non-exclusive logical OR, and should not be construed to mean “at least one of A, at least one of B, and at least one of C.”

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A thermal insulation device comprising:
an insulation layer having a first surface proximate a cooling device and a second surface opposing the first surface;
a heater layer disposed proximate the second surface; and
a protective layer disposed proximate the heater layer such that the heater layer is disposed between the insulation layer and the protective layer.

2. The thermal insulation device according to claim 1, wherein the insulation layer defines a tubular body, the first surface being an inner surface and the second surface being an outer surface of the tubular body.

3. The thermal insulation device according to claim 2, wherein the heater layer surrounds the insulation layer, and the protective layer surrounds the heater layer.

4. The thermal insulation device according to claim 1, wherein the heater layer is configured to reduce frost or ice buildup on an exterior surface of the insulation layer.

5. The thermal insulation device according to claim 1, further comprising a vapor barrier layer disposed between the protective layer and the insulation layer.

6. The thermal insulation device according to claim 1, wherein the insulation layer includes a material selected from a group consisting of polyisocyanurate, polyurethane, expanded polystyrene, silicone foam, polyethylene foam, aerogels, and combinations thereof.

7. The thermal insulation device according to claim 1, wherein the insulation layer includes a monolith body.

8. The thermal insulation device according to claim 1, wherein the insulation layer comprises a composite structure.

9. The thermal insulation device according to claim 1, wherein the insulation layer includes an aerogel material as a primary constituent.

10. The thermal insulation device according to claim 1, further comprising a dielectric layer and a vapor barrier layer disposed between the protective layer and the insulation layer.

11. The thermal insulation device according to claim 10, wherein the vapor barrier layer is an aluminum material.

12. The thermal insulation device according to claim 10, wherein the vapor barrier layer is a metal thin film on a polymer film.

13. The thermal insulation device according to claim 10, wherein the dielectric layer is a polyimide material or a reinforced silicone rubber material.

14. The thermal insulation device according to claim 1, wherein the heater layer comprises a polyimide heater.

15. The thermal insulation device according to claim 1, wherein the heater layer comprises a layered heater.

16. The thermal insulation device according to claim 1, further comprising a power generating device for supplying an induced voltage to the heater layer, wherein the induced voltage is induced by a temperature difference in the power generating device.

17. The thermal insulation device according to claim 16, wherein the power generating device includes a first conductive portion and a second conductive portion that are joined and that are made of different materials.

18. The thermal insulation device according to claim 17, wherein the first and second conductive portions are disposed proximate external components having different temperatures such that the temperature difference is generated between the first and second conductive portions.

19. A thermal insulation device comprising:
a tubular insulation layer defining a central opening for receiving a coolant conduit therein;
a heater layer disposed around the tubular insulation layer;
a protective layer disposed around the heater layer;
a dielectric layer disposed between the heater layer and the protective layer; and
a vapor barrier layer disposed between the heater layer and the protective layer.

20. A thermal insulation device comprising:
a tubular insulation layer defining a central opening for receiving a coolant conduit therein;
a protective layer disposed around the tubular insulation layer;
a heater layer disposed around the protective layer;
a dielectric layer disposed between the heater layer and the protective layer; and
a vapor barrier layer disposed between the heater layer and the protective layer.
